(19) United States
(12) Patent Application Publication
(10) Pub. No.: US 2026/0051856 A1
(43) Pub. Date: Feb. 19, 2026

(54) AUTOMATED MATCHING NETWORK

(71) Applicant: SKYWORKS SOLUTIONS, INC., Irvine, CA (US)

(72) Inventor: Neal J. Tuffy, Malahide (IE)

(21) Appl. No.: 19/280,865

(22) Filed: Jul. 25, 2025

Related U.S. Application Data
(60) Provisional application No. 63/669,790, filed on Jul. 11, 2024.

(51) Int. Cl. H03F 1/56; H03F 3/24

(52) U.S. Cl. CPC H03F 1/565; H03F 3/245; H03F 2200/451

(57) ABSTRACT

A device may receive a radio-frequency (RF) signal at a multi-mode power amplifier. A device may generate a load line for a first mode and a second mode based on the RF signal. A device may determine whether the load line is outside a first target zone for the first mode. A device may in response to determining that the load line is outside the first target zone, generating a first penalty value. A device may adjust inductance or capacitance values at the multi-mode power amplifier in response to the first penalty value.

### RELATED APPLICATION

This application claims priority to U.S. Provisional Application No. 63/669,790, filed Jul. 11, 2024, and entitled AUTOMATED MATCHING NETWORK, the disclosure of which is hereby incorporated by reference in its entirety.

### BACKGROUND

The present disclosure generally relates to the field of electronics, and more particularly, to radio-frequency (RF) modules and devices. RF signals can be amplified using power amplifier (PA) circuitry.

### SUMMARY

In some implementations, the present disclosure relates to a method including receiving a radio-frequency (RF) signal at a multi-mode power amplifier; generating a load line for a first mode and a second mode based on the RF signal; determining whether the load line is outside a first target zone for the first mode; in response to determining that the load line is outside the first target zone, generating a first penalty value; and adjusting inductance or capacitance values at the multi-mode power amplifier in response to the first penalty value.

In some aspects, the techniques described herein relate to a method further including determining whether the load line is outside a second target zone for the second mode.

In some aspects, the techniques described herein relate to a method further including, in response to determining that the load line is outside the second target zone, generating a second penalty value.

In some aspects, the techniques described herein relate to a method further including adjusting inductance or capacitance values at the multi-mode power amplifier in response to the second penalty value.

In some aspects, the techniques described herein relate to a method wherein generating the first penalty value is based on a distance of the load line from the first target zone.

In some aspects, the techniques described herein relate to a method wherein the RF signal is a Wi-Fi or Bluetooth signal.

In some aspects, the techniques described herein relate to a method further including determining a first distance between the load line and the first target zone, wherein generating the first penalty value is based at least in part on the determined distance.

In some aspects, the techniques described herein relate to a method wherein the first penalty value is proportional to a distance between the load line and the first target zone.

In some aspects, the techniques described herein relate to a method further including generating a sum by adding the first penalty value to a loss value associated with the first mode.

In some aspects, the techniques described herein relate to a method wherein the adjusting the inductance or capacitance values is based at least in part on the sum.

Some implementations of the present disclosure relate to a method including receiving a radio-frequency (RF) signal at a multi-mode power amplifier; generating a load line for a first mode and a second mode based on the RF signal; determining whether the load line is outside a first target zone for the first mode; determining whether the load line is outside a second target zone for the second mode; in response to determining that the load line is outside the first target zone, generating a first penalty value; in response to determining that the load line is outside the second target zone, generating a second penalty value; and adjusting inductance or capacitance values at the multi-mode power amplifier in response to the first penalty value and the second penalty value.

In some aspects, the techniques described herein relate to a method wherein generating the first penalty value is based on a distance of the load line from the first target zone.

In some aspects, the techniques described herein relate to a method wherein the RF signal is a Wi-Fi or Bluetooth signal.

In some aspects, the techniques described herein relate to a method further including determining a first distance between the load line and the first target zone, wherein generating the first penalty value is based at least in part on the determined distance.

In some aspects, the techniques described herein relate to a method wherein the first penalty value is proportional to a distance between the load line and the first target zone.

In accordance with one or more implementations, the present disclosure relates to a wireless device including a sub-system storing instructions to cause the wireless device to: receive a radio-frequency (RF) signal at a multi-mode power amplifier; generate a load line for a first mode and a second mode based on the RF signal; determine whether the load line is outside a first target zone for the first mode; in response to determining that the load line is outside the first target zone, generate a first penalty value; and adjust inductance or capacitance values at the multi-mode power amplifier in response to the first penalty value.

In some aspects, the techniques described herein relate to a wireless device wherein the instructions further cause the wireless device to determine whether the load line is outside a second target zone for the second mode.

In some aspects, the techniques described herein relate to a wireless device wherein the instructions further cause the wireless device to, in response to determining that the load line is outside the second target zone, generate a second penalty value.

In some aspects, the techniques described herein relate to a wireless device wherein the instructions further cause the wireless device to adjust inductance or capacitance values at the multi-mode power amplifier in response to the second penalty value.

In some aspects, the techniques described herein relate to a wireless device wherein the first penalty value is proportional to a distance between the load line and the first target zone.

### BRIEF DESCRIPTION OF THE DRAWINGS

Various embodiments are depicted in the accompanying drawings for illustrative purposes, and should in no way be interpreted as limiting the scope of the inventions. In addition, various features of different disclosed embodiments can be combined to form additional embodiments, which are part of this disclosure. Throughout the drawings, reference numbers may be reused to indicate correspondence between reference elements.

FIG. 1 illustrates a wireless system or architecture having an amplification system.

FIG. 2 shows the amplification system of FIG. 1 including a radio-frequency (RF) amplifier assembly having one or more power amplifiers (PAS).

FIG. 3 illustrates an example matching network of a power amplifier in accordance with one or more examples.

FIG. 4 illustrates a graph of potential impedance load value values (e.g., load lines) that may be applied to an OMN in accordance with one or more examples.

FIG. 5 provides a graph illustrating example loss values for a first mode and/or a second mode.

FIG. 6 illustrates another graph of potential impedance load value values (e.g., load lines) that may be applied to an OMN in accordance with one or more examples.

FIG. 7 provides a flowchart illustrating an example process matching loads within a multi-mode power amplifier in accordance with one or more examples.

FIG. 8 shows that in some embodiments, some or all of the power amplification systems described herein can be implemented in a module.

FIG. 9 depicts an example wireless device having one or more advantageous features described herein.

### DESCRIPTION

The headings provided herein, if any, are for convenience only and do not necessarily affect the scope or meaning of the claimed invention.

The present disclosure generally relates to the field of electronics, and more particularly, to radio-frequency (RF) modules and devices. RF signals can be amplified using power amplifier (PA) circuitry.

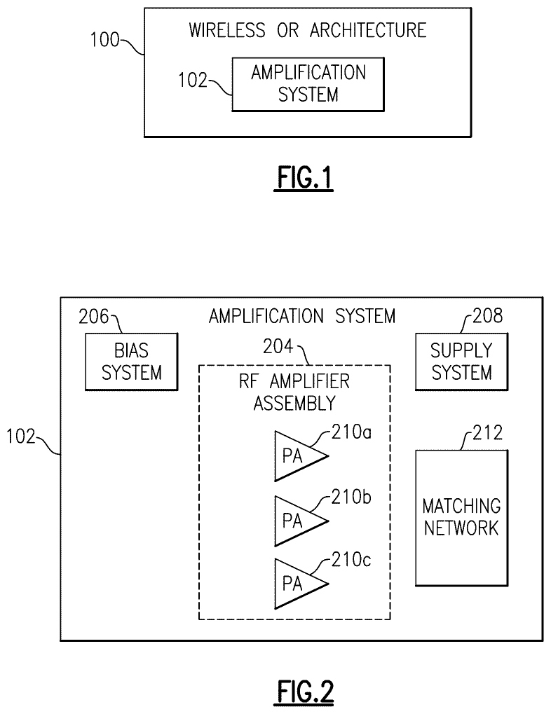

Referring to FIG. 1, one or more features of the present disclosure generally relate to a wireless system or architecture 100 having an amplification system 102. In some embodiments, the amplification system 102 can be implemented as one or more devices, and such device(s) can be utilized in the wireless system/architecture 100. In some embodiments, the wireless system/architecture 100 can be implemented in, for example, a portable wireless device. Examples of such a wireless device are described herein.

FIG. 2 shows the amplification system 102 of FIG. 1 including a radio-frequency (RF) amplifier assembly 204 having one or more power amplifiers (PAS). In the example of FIG. 2, three PAs 210a-210c are depicted as forming the RF amplifier assembly 204. It will be understood that other numbers of PA(s) can also be implemented. It will also be understood that one or more features of the present disclosure can also be implemented in RF amplifier assemblies having other types of RF amplifiers.

In some embodiments, the RF amplifier assembly 204 can be implemented on one or more semiconductor dies, and such die can be included in a packaged module such as a power amplifier module (PAM) or a front-end module (FEM). Such a packaged module may be mounted on a circuit board associated with, for example, a portable wireless device.

The PAs (e.g., 210a-210c) in the amplification system 102 can be biased by a bias system 206. Further, supply voltages for the PAs are typically provided by a supply system 208. In some embodiments, either or both of the bias system 206 and the supply system 208 can be included in the foregoing packaged module having the RF amplifier assembly 204.

In some embodiments, the amplification system 102 can include a matching network 212. Such a matching network can be configured to provide input matching and/or output matching functionalities for the RF amplifier assembly 204.

Some power amplifiers can be configured to operate in multiple modes and/or to perform in different ways in different modes. For example, a power amplifier may be configured to operate in a high-power mode (e.g., Wi-Fi) and/or in a low-power mode (e.g., Bluetooth). These different modes may have different requirements. A power amplifier may comprise an output matching network (OMN) configured to perform matching between multiple modes. The OMN may be a key part in determining performance characteristics of the power amplifier.

As the number of modes handled by the power amplifier increases, the complexity at the OMN increases. In some cases, a greater number of modes may involve use of more components. In some examples, multiple modes may be handled by switching components in and out through use of one or more switches.

FIG. 3 illustrates an example matching network 300 of a power amplifier in accordance with one or more examples. The network 300 can comprise one or more switches 302 configured to support multiple load lines. The switches 302 can be implemented on silicon-on-insulator (SOI). In some examples, each switch 302 may be coupled between a shunt capacitor 304 and/or a series inductor 306.

Use of lossy switches 302 can dramatically increase OMN loss. In some examples, a high-order network may be required to hit required load line impedances in each mode simultaneously with low power loss. As a result, the OMN may be highly complex to ensure minimum loss in each mode.

Manual tuning of a multi-mode power amplifier may be highly complex and/or the complexity can increase exponentially with each additional mode. Determining a specific load in multiple modes and/or simultaneously minimizing loss can be demanding for manual tuning of high-order OMNs.

Automated optimization for multi-objective and/or multi-variable OMN designs can minimize losses and/or provide relative high efficiency. Systems and/or methods described herein advantageously provide automated matching, which can allow designers to assess more OMN topologies relative to manual design procedures.

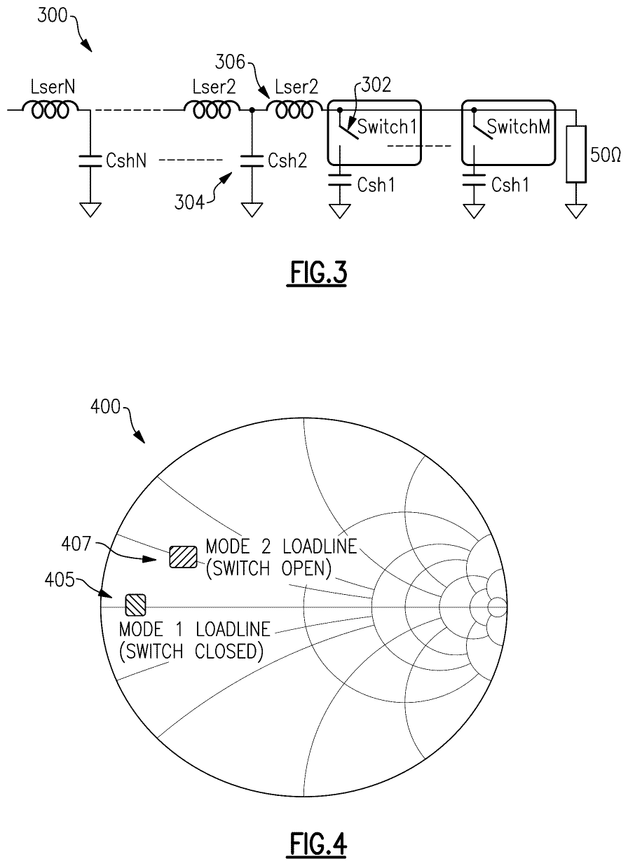

FIG. 4 illustrates a graph 400 of potential impedance load value values (e.g., load lines) that may be applied to an OMN in accordance with one or more examples. Multi-mode OMN designs described herein can involve load line region definitions. The load lines can fall anywhere within the graph 400. In some examples, the graph 400 can include one or more target regions, including a first target region 405 (e.g., associated with a first mode) and/or a second target region 407 (e.g., associated with a second mode). While only two target regions are shown, there may be more target regions (e.g., where there are more than two modes).

A process of impedance matching may involve determining whether a measured load line falls within the first target region 405 and/or the second target region 407. Where the measured load line is outside the first target region 405 and/or second target region 407, it may be determined how far the load line is from the first target region 405 and/or second target region 407. Load lines outside the first target region 405 and/or second target region 407 may trigger a penalty to the OMN and/or OMN optimization algorithm and/or processor that may be proportional to the distance the load line is from the first target region 405 and/or second target region 407. In some examples, a penalty may be determined through use of an optimization objective function.

In one example an initial tune may generate a load line at a matching network that equals 7+j3 in a first mode with 1.5 dB loss and/or equals 15+j15 in a second mode with 2.5 dB loss. For the first target region 405 (e.g., first mode), where 5.5 is a center of the first target region 405 in a first axis, 7 is a measured value in the first axis, 3 is a center of the first target region 405 in a second axis, and/or 0.5 is a measured value in the second axis, computing distance from the load line may determine a penalty for the first mode of (7−5.5)+(3−0.5)=4. For the second target region 407 (e.g., second mode), where 12 is a center of the second target region 407 in the first axis, 15 is a measured value in the first axis, 11 is a center of the second target region 407 in the second axis, and/or 15 is a measured value in the second axis, computing distance from the load line may determine a penalty for the second mode of (15−12)+(15−11)−7. An OMN loss for the first mode may be a first raw OMN loss amount for a first tune and/or mode (e.g., 1.5) added to the penalty for the first tune (4), resulting in a loss of 1.5+4=5.5. Similarly, the OMN loss for the second mode may be a second raw OMN loss amount for a second tune and/or mode (e.g., 2.5) added to the penalty for the second tune and/or mode (7), resulting in 2.5+7=9.5. A goal of an optimization function on each iteration may be to minimize the sum of these two numbers and/or other the total loss. In this specific case/iteration, the objective function value is found to be 5+9.5=14.

If the load line lands within its target zone (405 or 407), then there may be no impedance loss penalty. Subsequently, the objective function value may be purely determined by the addition of the absolute value of the OMN losses in each mode. This implies the optimization procedure will aim to land the load lines in the impedance correct zones, whilst simultaneously attempting to minimize the OMN losses. This procedure tends to generate a large set of solutions that are compliant with load line zones, and that also explore the trade-off between losses in the various modes considered in the design process.

In some examples, impedance matching may utilize genetic algorithms and/or similar methods in a selection process to maximize impedance and/or other variables. Impedance values of one or more series inductors and/or capacitance values of one or more shunt capacitors may be changed as needed to reach load lines that fall within the first target region 405 and/or second target region 407. Use of genetic algorithms can allows for identifying multi-modal solutions and/or Pareto optimal solutions. All solutions that may be viable options may be returned given asset of conflicting constraints.

The series inductors and/or shunt capacitors may be continuous variables and/or can have any values. Applying penalties to the inductor and/or capacitor values can adjust matching to achieve inductor and/or capacitor values within the target ranges. In some examples, the further the measured inductor and/or capacitor values are from the target regions, the greater the penalty applied to the measure values may be. Penalties and/or adjustments may be applied in an iterative loop until a desired outcome is achieved. Loss line values falling within the target areas may not incur any penalty.

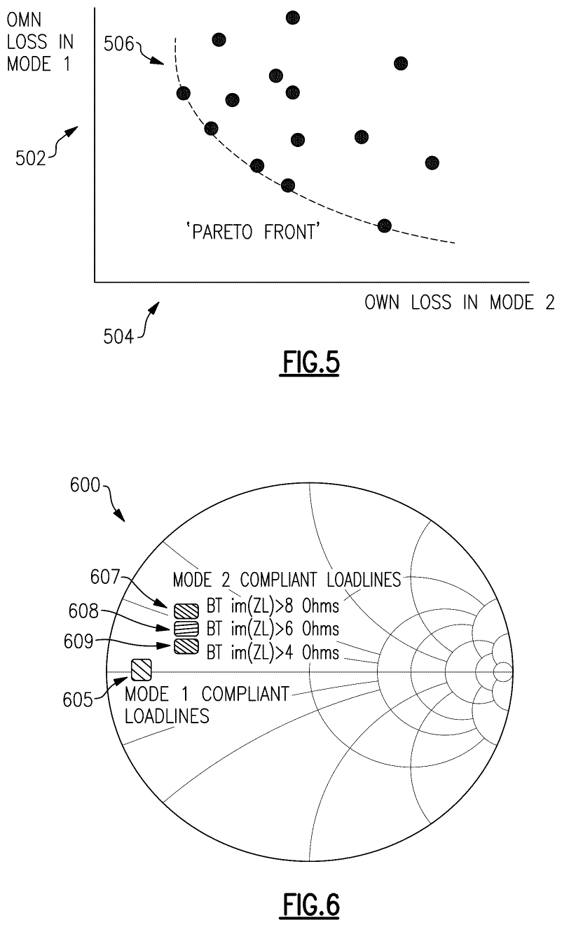

FIG. 5 provides a graph 500 illustrating example loss values for a first mode 502 and/or a second mode 504. Systems and/or methods described herein may be configured to optimize losses for multiple modes, which may achieve outcomes along a loss minimization curve 506. Over time, systems may be configured to minimize losses for multiple modes with greater accuracy.

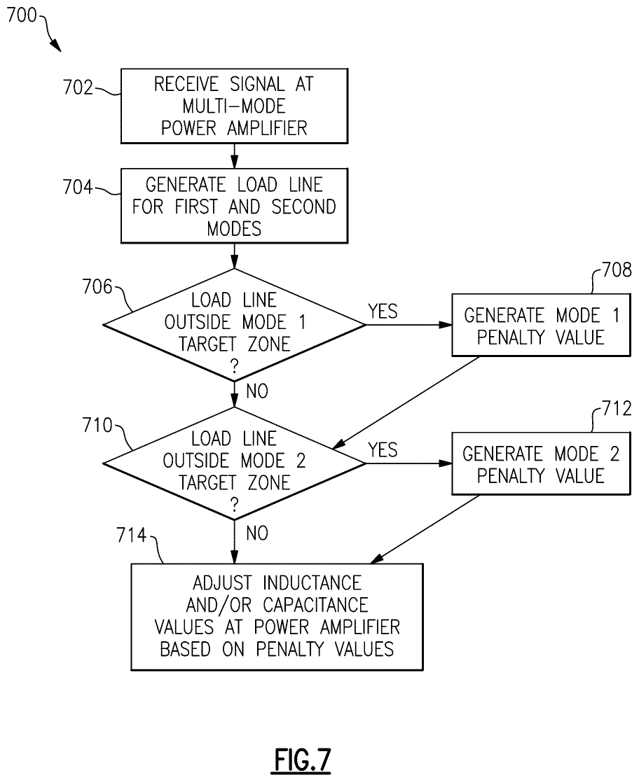

FIG. 6 illustrates another graph 600 of potential impedance load value values (e.g., load lines) that may be applied to an OMN in accordance with one or more examples. In some examples, one or more modes may have different target load regions based on desired load line values. In the example shown in FIG. 6, a first mode may have a first target zone 605 and/or a second mode may have three target zones, which may include a second target zone 607, a third target zone 608, and/or a fourth target zone 609. The second target zone 607, third target zone 608, and/or fourth target zone 69 may be alternately applied based on a desired load line. For example, the second target zone 607 may be used for load lines greater than 8Ω, the third target zone 608 may be used for load lines greater than 6Ω and/or less than 8Ω, and/or the third target zone 609 may be used for load lines greater than 4Ω and/or less than 6Ω.

FIG. 7 provides a flowchart illustrating an example process 700 matching loads within a multi-mode power amplifier in accordance with one or more examples.

At a step 702, the process 700 involves receiving one or more signals at the power amplifier. The one or more signals may include Wi-Fi and/or Bluetooth (BT) signals.

At a step 704, the process 700 involves generating a load line for multiple modes, which may include at least a first mode and/or a second mode.

At a first decision block 706, the process 700 involves determining whether the generated load line is outside a target zone for the first mode. If the generated load line is outside the target zone for the first mode, the process 700 continues to a step 708, which involves generating a penalty value for the first mode. The generated penalty value may be based at least part on a measured distance of the load line from the target zone for the first mode. For example, the further from the target zone for the first mode, the greater the penalty value for the first mode may be.

At a second decision block 710, the process 700 involves determining whether the generated load line is outside a target zone for the second mode. If the generated load line is outside the target zone for the second mode, the process 700 continues to a step 712, which involves generating a penalty value for the second mode. The generated penalty value may be based at least part on a measured distance of the load line from the target zone for the second mode. For example, the further from the target zone for the second mode, the greater the penalty value for the second mode may be.

At a step 714, the process 700 involves adjusting inductance and/or capacitance values at the power amplifier based at least in part on the penalty values for the first mode and/or second mode.

The systems and/or methods described herein may utilize a multi-objective optimization routine to deliver improved matching network performance. In some examples, automated optimization tools described herein can utilize a Python (or similar) based script implementation of a Non-Dominated Sorting Genetic Algorithm II (NSGA-II) optimization algorithm and/or other Genetic Algorithm for solving optimization problems with multi-objectives.

In some examples, OMN load line objectives may be converted to a penalty function rather than used strictly as an objective. This can advantageously simplify algorithms by reducing the number of objectives to the OMN losses. Such systems can effectively target the load line compliant region and/or allow rapid characterization of the search space to quickly identify global optimum and/or pareto optimum solutions.

Compliance regions can be shifted (e.g., after characterization) to identify the performance (e.g., OMN losses) when a mode load line impedance is changed (e.g., to ultimately reduce current at the expense of power). This may provide a robust optimization procedure that fully characterizes the OMN topology for any number of load lines. Additional objectives (e.g., harmonic rejection) can be added.

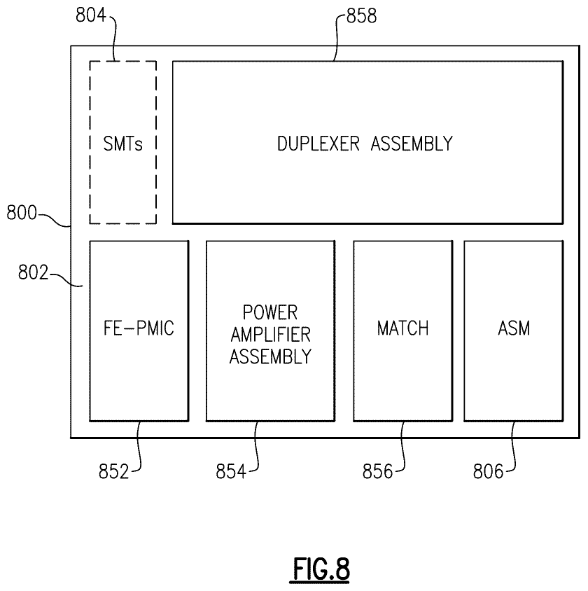

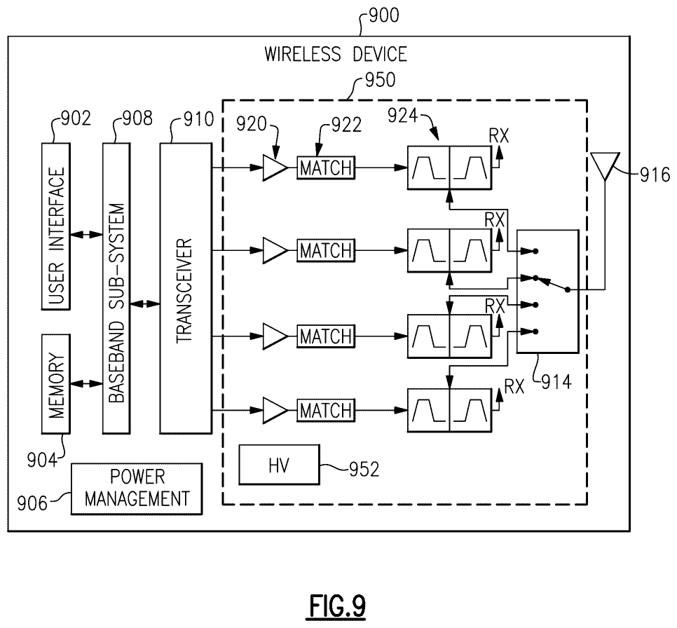

FIG. 8 shows that in some embodiments, some or all of the power amplification systems described herein can be implemented in a module. Such a module can be, for example, a front-end module (FEM). In the example of FIG. 8, a module 800 can include a packaging substrate 802, and a number of components can be mounted on such a packaging substrate. For example, an FE-PMIC component 852, a power amplifier assembly 854, a match component 856, and a duplexer assembly 858 can be mounted and/or implemented on and/or within the packaging substrate 802. Other components such as a number of SMT devices 804 and an antenna switch module (ASM) 806 can also be mounted on the packaging substrate 802. Although all of the various components are depicted as being laid out on the packaging substrate 802, it will be understood that some component(s) can be implemented over other component(s).

In some implementations, a device and/or a circuit having one or more features described herein can be included in an RF device such as a wireless device. Such a device and/or a circuit can be implemented directly in the wireless device, in a modular form as described herein, or in some combination thereof. In some embodiments, such a wireless device can include, for example, a cellular phone, a smart-phone, a hand-held wireless device with or without phone functionality, a wireless tablet, etc.

FIG. 9 depicts an example wireless device 900 having one or more advantageous features described herein. In the context of a module having one or more features as described herein, such a module can be generally depicted by a dashed box 950, and can be implemented as, for example, a front-end module (FEM).

Referring to FIG. 9, power amplifiers (PAS) 920 can receive their respective RF signals from a transceiver 910 that can be configured and operated in known manners to generate RF signals to be amplified and transmitted, and to process received signals. The transceiver 910 is shown to interact with a baseband sub-system 908 that is configured to provide conversion between data and/or voice signals suitable for a user and RF signals suitable for the transceiver 910. The transceiver 910 can also be in communication with a power management component 906 that is configured to manage power for the operation of the wireless device 900. Such power management can also control operations of the baseband sub-system 908 and the module 950.

The baseband sub-system 908 is shown to be connected to a user interface 902 to facilitate various input and output of voice and/or data provided to and received from the user. The baseband sub-system 908 can also be connected to a memory 904 that is configured to store data and/or instructions to facilitate the operation of the wireless device, and/or to provide storage of information for the user.

In the example wireless device 900, outputs of the PAs 920 are shown to be matched (via respective match circuits 922) and routed to their respective duplexers 924. In some embodiments, the match circuit 922 can include matching circuits. The outputs of the PAs 920 can be routed to their respective duplexers 924 without impedance transformation when the PAs 920 are operated with HV supply 952. Such amplified and filtered signals can be routed to an antenna 916 through an antenna switch 914 for transmission. In some embodiments, the duplexers 924 can allow transmit and receive operations to be performed simultaneously using a common antenna (e.g., 916). In FIG. 9, received signals are shown to be routed to “Rx” paths (not shown) that can include, for example, a low-noise amplifier (LNA).

A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

As described herein, one or more features of the present disclosure can provide a number of advantages when implemented in systems such as those involving the wireless device of FIG. 9. For example, significant current drain reduction can be achieved through an elimination or reduction of output loss. In another example, lower bill of materials count can be realized for the power amplification system and/or the wireless device. In yet another example, independent optimization or desired configuration of each supported frequency band can be achieved due to, for example, separate PAs for their respective frequency bands. In yet another example, optimization or desired configuration of maximum or increased output power can be achieved through, for example, a boost supply voltage system. In yet another example, a number of different battery technologies can be utilized, since maximum or increased power is not necessarily limited by battery voltage.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number, respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions, and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A method comprising:
receiving a radio-frequency (RF) signal at a multi-mode power amplifier;
generating a load line for a first mode and a second mode based on the RF signal;
determining whether the load line is outside a first target zone for the first mode;
in response to determining that the load line is outside the first target zone, generating a first penalty value; and
adjusting inductance or capacitance values at the multi-mode power amplifier in response to the first penalty value.

2. The method of claim 1 further comprising determining whether the load line is outside a second target zone for the second mode.

3. The method of claim 2 further comprising, in response to determining that the load line is outside the second target zone, generating a second penalty value.

4. The method of claim 3 further comprising adjusting inductance or capacitance values at the multi-mode power amplifier in response to the second penalty value.

5. The method of claim 1 wherein generating the first penalty value is based on a distance of the load line from the first target zone.

6. The method of claim 1 wherein the RF signal is a Wi-Fi or Bluetooth signal.

7. The method of claim 1 further comprising determining a first distance between the load line and the first target zone, wherein generating the first penalty value is based at least in part on the determined distance.

8. The method of claim 1 wherein the first penalty value is proportional to a distance between the load line and the first target zone.

9. The method of claim 1 further comprising generating a sum by adding the first penalty value to a loss value associated with the first mode.

10. The method of claim 9 wherein the adjusting the inductance or capacitance values is based at least in part on the sum.

11. A method comprising:
receiving a radio-frequency (RF) signal at a multi-mode power amplifier;
generating a load line for a first mode and a second mode based on the RF signal;
determining whether the load line is outside a first target zone for the first mode;
determining whether the load line is outside a second target zone for the second mode;
in response to determining that the load line is outside the first target zone, generating a first penalty value;
in response to determining that the load line is outside the second target zone, generating a second penalty value; and
adjusting inductance or capacitance values at the multi-mode power amplifier in response to the first penalty value and the second penalty value.

12. The method of claim 11 wherein generating the first penalty value is based on a distance of the load line from the first target zone.

13. The method of claim 11 wherein the RF signal is a Wi-Fi or Bluetooth signal.

14. The method of claim 11 further comprising determining a first distance between the load line and the first target zone, wherein generating the first penalty value is based at least in part on the determined distance.

15. The method of claim 11 wherein the first penalty value is proportional to a distance between the load line and the first target zone.

16. A wireless device comprising:
a sub-system storing instructions to cause the wireless device to:
receive a radio-frequency (RF) signal at a multi-mode power amplifier;
generate a load line for a first mode and a second mode based on the RF signal;
determine whether the load line is outside a first target zone for the first mode;
in response to determining that the load line is outside the first target zone, generate a first penalty value; and
adjust inductance or capacitance values at the multi-mode power amplifier in response to the first penalty value.

17. The wireless device of claim 16 wherein the instructions further cause the wireless device to determine whether the load line is outside a second target zone for the second mode.

18. The wireless device of claim 17 wherein the instructions further cause the wireless device to, in response to determining that the load line is outside the second target zone, generate a second penalty value.

19. The wireless device of claim 18 wherein the instructions further cause the wireless device to adjust inductance or capacitance values at the multi-mode power amplifier in response to the second penalty value.

20. The wireless device of claim 16 wherein the first penalty value is proportional to a distance between the load line and the first target zone.
